(19) United States
(12) Patent Application Publication
(10) Pub. No.: US 2019/0140198 A1
(43) Pub. Date: May 9, 2019

(54) A FLEXIBLY FOLDABLE DISPLAY PANEL

(71) Applicant: Wuhan China Star Optoelectronics Semiconductor Display Technology Co., Ltd., Wuhan, Hubei (CN)

(72) Inventor: Jun LI, Wuhan, Hubei (CN)

(21) Appl. No.: 15/745,126

(22) PCT Filed: Nov. 16, 2017
(86) PCT No.: PCT/CN2017/111369

§ 371 Date: Jan. 15, 2018

(30) Foreign Application Priority Data
Nov. 8, 2017 (CN) 201711093250.4

(51) Int. Cl. H01L 51/00; G09G 3/3208; H01L 27/32

(52) U.S. Cl. CPC H01L 51/0097; H01L 27/3276; G09G 3/3208

(57) ABSTRACT

The present invention provides a flexibly foldable display panel, which comprises at least two non-foldable regions and a foldable region between the two adjacent non-foldable regions. Two sides of the foldable region are respectively connected with the two adjacent non-foldable regions and formed a one-piece structure therewith. Each of the non-foldable regions is provided with a GOA circuit unit. The at least two non-foldable regions contain all GOA circuit units in the display panel, and the GOA circuit units in the two non-foldable regions are electrically connected to each other. By means of the flexibly foldable display panel provided by the present invention, the GOA circuit unit is prevented from damage when the display panel is in a bending action, and thus the display effect of the display panel is ensured.

### RELATED APPLICATIONS

The present application is a National Phase of International Application Number PCT/CN2017/111369, filed Nov. 16, 2017, and claims the priority of China Application No. 201711093250.4, filed Nov. 8, 2017.

### FIELD OF THE DISCLOSURE

The disclosure relates to a display technical field, and more particularly to a flexibly foldable display panel.

### BACKGROUND

AMOLED (Active Array Organic Light Emitting Display) panels have great competitiveness in new era of displays due to their slim, high contrast, and foldable features. A flexibly foldable technology generally requests that the performance characteristic of a flexible display device does not drift greatly under the action of stress. That is, the draft rate of a thin film transistor in the panel cannot be too serious, the threshold voltage of a N-type thin film transistor cannot drift to a negative value, the threshold voltage of a P-type thin film transistor cannot drift to a positive value, and the turn-off current of the thin film transistor cannot be too high. When the flexible display device is bent, the GOA circuit may be damaged, which may cause the performance of the flexible display device to drift greatly and cause the display of the panel to be poor.

### SUMMARY

In order to solve the above technical problem, the present invention provides a flexibly foldable display panel, which can protect the GOA circuit unit from damage and ensure the display effect of the display panel when the display panel is bent.

The present invention provides a flexibly foldable display panel, comprising: at least two non-foldable regions, and a foldable region between the two adjacent non-foldable regions, wherein two sides of the foldable region are respectively connected with the two adjacent non-foldable regions and formed a one-piece structure therewith.

Each of the non-foldable regions is provided with a GOA circuit unit. The at least two non-foldable regions contain all GOA circuit units in the display panel and the GOA circuit units in the two non-foldable regions are electrically connected to each other.

Preferably, the foldable region is provided with metal lines and an organic layer upwardly on a substrate, and the non-foldable region is provided with an inorganic layer, metal lines, the GOA circuit unit and an organic layer upwardly on a substrate.

Preferably, the display panel includes an effective display area and a non-effective display area around the effective display area. The GOA circuit unit is located in the non-effective display area, and the GOA circuit unit is electrically connected to the effective display area.

Preferably, the GOA circuit unit is connected to the effective display area through one or more gate lines.

Preferably, the lengths of the lines from the GOA circuit unit to the effective display area are all the same.

Preferably, a part of the metal line located in the foldable region is in a shape of S, arc, or folding when it is projected on the substrate.

Preferably, the parts of various metal lines which are located in the foldable region are the same in length.

Preferably, the inorganic layer comprises SiNₓ and/or SiO_{y}, wherein x≥1 and y≥1.

Preferably, the substrate is made of a polyimide material.

Preferably, the organic layer is a photoresist material or an organic insulating material.

The present invention further provides a flexibly foldable display panel, comprising: at least two non-foldable regions, and a foldable region between the two adjacent non-foldable regions, wherein two sides of the foldable region are respectively connected with the two adjacent non-foldable regions and formed a one-piece structure therewith.

Each of the non-foldable regions is provided with a GOA circuit unit. The at least two non-foldable regions contain all GOA circuit units in the display panel and the GOA circuit units in the two non-foldable regions are electrically connected to each other.

The foldable region is provided with metal lines and an organic layer upwardly on a substrate, and the non-foldable region is provided with an inorganic layer, metal lines, the GOA circuit units and an organic layer upwardly on a substrate.

The display panel includes an effective display area and a non-effective display area around the effective display area. The GOA circuit units are located in the non-effective display area, and the GOA circuit units are electrically connected to the effective display area.

The parts of various metal lines which are located in the foldable region are the same in length.

Preferably, the GOA circuit unit is connected to the effective display area through one or more gate lines.

Preferably, the lengths of the lines from the GOA circuit unit to the effective display area are all the same.

Preferably, a part of the metal line located in the foldable region is in a shape of S, arc, or foldable when it is projected on the substrate.

Preferably, the inorganic layer comprises SiNₓ and/or SiO_{y}, wherein x≥1 and y≥1.

The substrate is made of a polyimide material.

The organic layer is a photoresist material or an organic insulating material.

The present invention further provides a flexibly foldable display panel, comprising: at least two non-foldable regions, and a foldable region between the two adjacent non-foldable regions, wherein two sides of the foldable region are respectively connected with the two adjacent non-foldable regions and formed a one-piece structure therewith.

Each of the non-foldable regions is provided with a GOA circuit unit. The at least two non-foldable regions contain all GOA circuit units in the display panel and the GOA circuit units in the two non-foldable regions are electrically connected to each other.

The foldable region is provided with metal lines and an organic layer upwardly on a substrate, and the non-foldable region is provided with an inorganic layer, metal lines, the GOA circuit unit and an organic layer upwardly on a substrate.

A part of the metal line located in the foldable region is in a shape of S, arc, or folding when it is projected on the substrate.

The parts of various metal lines which are located in the foldable region are the same in length.

Preferably, the display panel includes an effective display area and a non-effective display area around the effective display area. The GOA circuit units are located in the non-effective display area, and the GOA circuit units are electrically connected to the effective display area.

Preferably, the GOA circuit unit is connected to the effective display area through one or more gate lines.

Preferably, the lengths of the lines from the GOA circuit unit to the effective display area are all the same.

Preferably, the inorganic layer comprises SiNₓ and/or SiO_{y}, wherein x≥1 and y≥1.

The substrate is made of a polyimide material.

The organic layer is a photoresist material or an organic insulating material.

The beneficial effect implemented by the present invention has the following. The flexibly foldable display panel provided by the present invention removes a GOA circuit unit within a foldable region, and move the GOA circuit unit to the non-foldable regions on both sides of the foldable region, so as to put all the GOA circuit units in the non-foldable regions. That is, the original GOA circuit unit located in the foldable region is moved to the non-foldable region. By means of that, the GOA circuit units are prevented from damage in a bending action. A problem of abnormal display on the display panel resulted from a damage to the GOA circuit unit or a reduction of the number of the GOA circuit units is also prevented. Thereby, display effect of the display panel is ensured.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a top view of a flexibly foldable display panel provided by the present invention.

FIG. 2 is a cross-sectional view of a flexibly foldable display panel provided by the present invention.

FIG. 3 is a top view of a flexibly foldable display panel according to another embodiment of the present invention.

### DETAILED DESCRIPTION OF PREFERRED EMBODIMENTS

The specific structural and functional details disclosed herein are only representative and are intended for describing exemplary embodiments of the disclosure. However, the disclosure can be embodied in many forms of substitution, and should not be interpreted as merely limited to the embodiments described herein.

In the description of the disclosure, terms such as “center”, “transverse”, “above”, “below”, “left”, “right”, “vertical”, “horizontal”, “top”, “bottom”, “inside”, “outside”, etc. for indicating orientations or positional relationships refer to orientations or positional relationships as shown in the drawings; the terms are for the purpose of illustrating the disclosure and simplifying the description rather than indicating or implying the device or element must have a certain orientation and be structured or operated by the certain orientation, and therefore cannot be regarded as limitation with respect to the disclosure. Moreover, terms such as “first” and “second” are merely for the purpose of illustration and cannot be understood as indicating or implying the relative importance or implicitly indicating the number of the technical feature. Therefore, features defined by “first” and “second” can explicitly or implicitly include one or more the features. In the description of the disclosure, unless otherwise indicated, the meaning of “plural” is two or more than two. In addition, the term “comprise” and any variations thereof are meant to cover a non-exclusive inclusion.

In the description of the disclosure, is should be noted that, unless otherwise clearly stated and limited, terms “mounted”, “connected with” and “connected to” should be understood broadly, for instance, can be a fixed connection, a detachable connection or an integral connection; can be a mechanical connection, can also be an electrical connection; can be a direct connection, can also be an indirect connection by an intermediary, can be an internal communication of two elements. A person skilled in the art can understand concrete meanings of the terms in the disclosure as per specific circumstances.

The terms used herein are only for illustrating concrete embodiments rather than limiting the exemplary embodiments. Unless otherwise indicated in the content, singular forms “a” and “an” also include plural. Moreover, the terms “comprise” and/or “include” define the existence of described features, integers, steps, operations, units and/or components, but do not exclude the existence or addition of one or more other features, integers, steps, operations, units, components and/or combinations thereof.

The disclosure will be further described in detail with reference to accompanying drawings and preferred embodiments as follows.

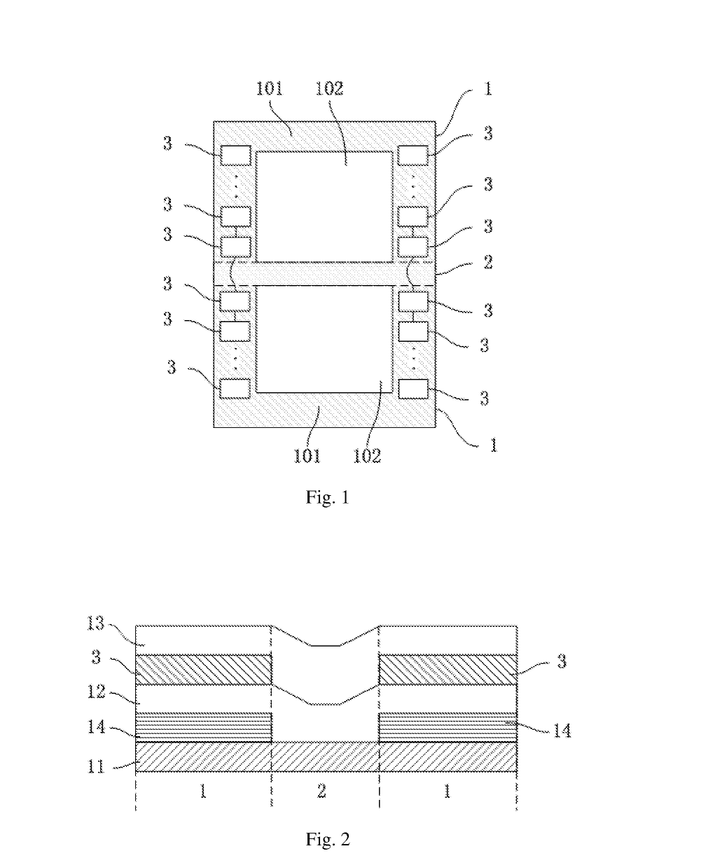

This embodiment of the present invention provides a flexibly foldable display panel. As shown in FIG. 1, the display panel comprises at least two non-foldable regions 1 and a foldable region 2 located between the two adjacent non-foldable regions 1. Both sides of the foldable region 2 are respectively connected with the two adjacent non-foldable regions 1 and are formed a one-piece structure therewith.

The non-foldable regions 1 are provided with GOA (Gate On Array) driving circuit units 3, wherein the at least two non-foldable regions 1 (that is, all non-foldable regions 1 of the display panel) comprises all the GOA circuit units 3 in the display panel, and the GOA circuit units 3 in the two non-foldable regions 1 are electrically connected together. The foldable area 2 is thus able to not include the GOA circuit unit 3.

Since the GOA circuit units 3 are disposed only in the non-foldable region 1 and the GOA circuit unit 3 is not provided in the foldable region 2, a damage to the GOA circuit units 3 will not happen when the display panel is folded along the foldable region 2, and thus a bending performance of the flexible display panel is improved. The total number of the GOA circuit units 3 in the non-foldable regions 1 is the same as the number of the gate lines in the display panel. In other words, the GOA circuit unit 3, such as GOA shift register circuit, in the prior foldable region 2 is moved to the non-foldable region 1. The number of the GOA circuit units 3 required for the display panel is not changed, so as to avoid the problem that the display panel cannot be normally displayed after digging out the GOA circuit units 3 in the foldable region 2.

Of course, the display panel according to the present invention may also have three or more non-foldable regions 1, and there is a foldable region 2 formed between two adjacent non-foldable regions 1.

Furthermore, as shown in FIG. 2, a metal line 12 and an organic layer 13 are disposed upwardly on a substrate 11 in the foldable region 2, and an inorganic layer 14, a metal line 12, a GOA circuit unit 3 and an organic layer 13 are disposed upwardly on the substrate 11 in the non-foldable region 1.

Since the inorganic layer 14 is very fragile and easily friable during a bending action and the inorganic layer 14 is not provided in the foldable region 2, a crack of the metal line 12 in the foldable region 2 resulted from a crack of the inorganic layer 14 during the bending action can be prevented, avoiding GOA circuit being failed caused by bending action.

Furthermore, the display panel includes an effective display area 102 and a non-effective display area 101 surrounding the effective display area 102. The GOA circuit units 3 are located in the non-effective display area 101, and the GOA circuit units 3 are electrically connected to the effective display area 102. Specifically, the GOA circuit units 3 are connected to the gates of the thin film transistors in the effective display area 102.

Furthermore, the GOA circuit unit 3 is connected to the effective display area 102 through one or more gate lines. For example, one GOA circuit unit 3 is connected to the effective display area 102 through one or two gate lines, and the effective display area 102 may also be accessed through three gate lines. The gate line may be a metal line.

Furthermore, the lengths of the lines from the GOA circuit units 3 into the effective display area 102 are all the same. For example, the lengths of the lines from various GOA circuit units 3 into the effective display area 102 are the same. When a GOA circuit unit 3 accesses the effective display area 102 through multiple lines, the lengths of the lines from the same GOA circuit unit 3 to the effective display area 102 are the same. The GOA circuit units 3 are electrically connected to the gate lines in the effective display area 102. The gate lines are electrically connected to the gates of the thin film transistors. The lengths of the lines from different GOA circuit units 3 to the effective display area 102 are the same. The impedance of the lines between different GOA circuit units 3 and the effective display area 102 thus can be the same for sure, so as to avoid difference in time delay of the signals from different GOA circuit units 3 to the effective display area 102, and to avoid an impact to the display effect of the display panel due to the different time delays of the signals output to the effective display area 102.

Furthermore, a part of the metal line 12 located in the foldable area 2 is in one of an S shape, an arc shape and a folding shape when it is projected on the substrate 11. By means of that, the bending property of the metal line 12 in the foldable area 2 can be enhanced. For example, the folding shape can be zigzag.

Furthermore, the lengths of the parts of various metal lines 12 located in the foldable region 2 are all the same, so as to ensure that the impedances of different metal lines 12 for connecting the GOA circuit units 3 are the same and to prevent difference in time delay for the signals output to different GOA circuit units 3 and difference in time delay for the signals output from different GOA circuit units 3 to the effective display area 102, which will affect the display effect of the effective display area 102.

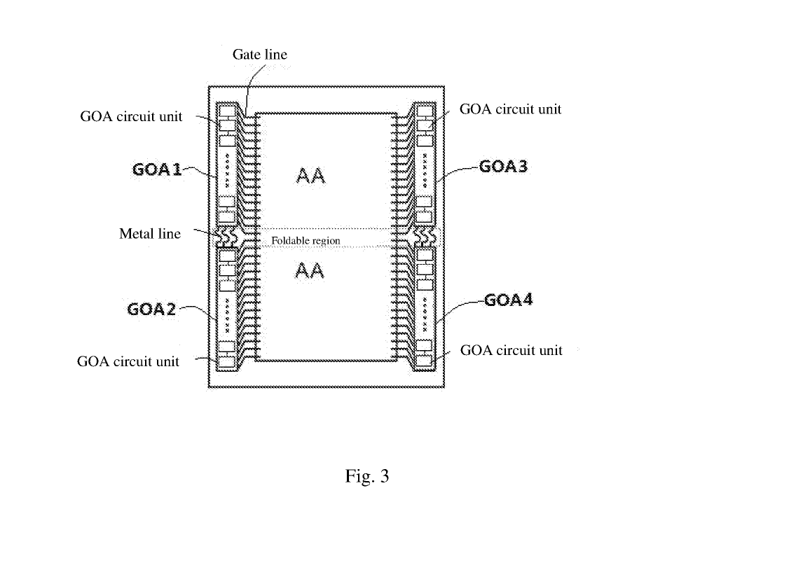

For example, as shown in FIG. 3, in another embodiment of the flexibly foldable display panel provided by the present invention, the display panel includes four GOA circuit regions GOA1, GOA2, GOA3, and GOA4. Each of the GOA1, GOA2, GOA3, and GOA4 includes multiple GOA circuit units. Each of the GOA circuit unit access an effective display area AA through a gate line. The GOA1 and GOA2 are connected by three metal lines. The lengths of the three metal lines in the foldable region are the same. The GOA3 and GOA4 are connected by three metal lines. The lengths of the three metal lines in the foldable region are also the same. The lengths of the metal lines between the GOA1 and GOA2 in the foldable region and the lengths of the lines 12 between the GOA3 and GOA4 in the foldable region are the same. This can avoids a difference in impedance between the metal lines resulted from different lengths of the metal lines between the GOA1 and GOA2, and the metal lines between the GOA3 and GOA4, and avoid affecting display effect due to inconsistent impedances of the metal lines.

Referring to FIG. 3 again, a part of the metal line between the GOA1 and the GOA2 that is located in the foldable area is in an S-shape when it is projected on the substrate. A part of the metal line between the GOA3 and the GOA4 that is located in the foldable area is in an S-shape when it is projected on the substrate. The lengths of the metal lines from the GOA1, the GOA2, the GOA3, and the GOA4 to the effective display area AA, i.e., gate lines, have the same length.

Furthermore, the inorganic layer 14 contains SiNx and/or SiOy, wherein x≥1 and y≥1. For example, the inorganic layer 14 may contain SiN and SiO.

Furthermore, the substrate 11 is made of a polyimide material.

Furthermore, the organic layer 13 comprises a photoresist material or an organic insulating material, and the organic layer 13 can insulate the film layers on both sides thereof.

In conclusion, according to the flexibly foldable display panel provided by the present invention, the GOA circuit unit 3 in the foldable region 2 is removed and put in the non-foldable region 1 on both sides of the foldable region 2. By means of moving the GOA circuit unit 3 originally in the foldable region 2 to the non-foldable region 1, the non-foldable region 1 includes all the GOA circuit units 3 in the display panel and the foldable region 2 does not contain the GOA circuit unit 3. That is, the GOA circuit unit 3 in the foldable region 2 is moved to the non-foldable region 1 to prevent the GOA circuit unit 3 from being damaged during a bending action and therefore to prevent the display panel from being displayed abnormally due to the damage to the GOA circuit unit 3 or a decrease in the number of GOA circuit units 3.

In addition, the present invention also removes an inorganic layer 14 from the foldable region 2, and retains the organic layer 13 and the metal lines 12 only, thereby preventing the bending process from causing the inorganic layer 14 to become brittle, and thereby preventing failure of the GOA circuit unit 3 due to a crack of the metal layer resulted from the brittleness of the inorganic layer 14.

Moreover, the metal line 12 between the two GOA circuit units 3 is also designed to a shape beneficial for bending, which prevents a crack of the metal line 12 in the foldable region 2 during a bending action, and prevents a poor display of the display panel due to the crack of the metal line 12.

In addition, the lengths of the different metal lines 12 in the foldable region 2 are the same, so that the impedances of different metal lines 12 are consistent and thus prevent from affecting the display effect of the display panel. The lengths of the metal lines from the GOA circuit unit 3 to the effective display area 102 are the same so as to ensure the same impedances of the metal lines from the GOA circuit unit 3 to the effective display area 102 and to avoid any influence on the display effect of the display panel.

The foregoing contents are detailed description of the disclosure in conjunction with specific preferred embodiments and concrete embodiments of the disclosure are not limited to these description. For the person skilled in the art of the disclosure, without departing from the concept of the disclosure, simple deductions or substitutions can be made and should be included in the protection scope of the application.

What is claimed is:

1. A flexibly foldable display panel, comprising at least two non-foldable regions and a foldable region between the two adjacent non-foldable regions, two sides of the foldable region being respectively connected with the two adjacent non-foldable regions and formed a one-piece structure therewith, wherein
each of the non-foldable regions is provided with a GOA circuit unit, the at least two non-foldable regions contain all GOA circuit units in the display panel, and the GOA circuit units in the two non-foldable regions are electrically connected to each other.

2. The flexibly foldable display panel according to claim 1, wherein the foldable region is provided with metal lines and an organic layer upwardly on a substrate, and the non-foldable region is provided with an inorganic layer, metal lines, the GOA circuit unit and an organic layer upwardly on a substrate.

3. The flexibly foldable display panel according to claim 2, wherein the display panel includes an effective display area and a non-effective display area around the effective display area, the GOA circuit unit is located in the non-effective display area, and the GOA circuit unit is electrically connected to the effective display area.

4. The flexibly foldable display panel according to claim 3, wherein the GOA circuit unit is connected to the effective display area through one or more gate lines.

5. The flexibly foldable display panel according to claim 4, wherein the lengths of the lines from the GOA circuit unit to the effective display area are all the same.

6. The flexibly foldable display panel according to claim 2, wherein a part of the metal line located in the foldable region is in a shape of S, arc, or folding when it is projected on the substrate.

7. The flexibly foldable display panel according to claim 2, wherein the parts of various metal lines which are located in the foldable region are the same in length.

8. The flexibly foldable display panel according to claim 2, wherein the inorganic layer comprises SiNx and/or SiOy, wherein x≥1 and y≥1.

9. The flexibly foldable display panel according to claim 2, wherein the substrate is made of a polyimide material.

10. The flexibly foldable display panel according to claim 2, wherein, the organic layer is a photoresist material or an organic insulating material.

11. A flexibly foldable display panel, comprising at least two non-foldable regions and a foldable region between the two adjacent non-foldable regions, two sides of the foldable region being respectively connected with the two adjacent non-foldable regions and formed a one-piece structure therewith, wherein
each of the non-foldable regions is provided with a GOA circuit unit, the at least two non-foldable regions contain all GOA circuit units in the display panel, and the GOA circuit units in the two non-foldable regions are electrically connected to each other,
the foldable region is provided with metal lines and an organic layer upwardly on a substrate, and the non-foldable region is provided with an inorganic layer, metal lines, the GOA circuit unit and an organic layer upwardly on a substrate,
the display panel includes an effective display area and a non-effective display area around the effective display area, the GOA circuit unit is located in the non-effective display area, and the GOA circuit unit is electrically connected to the effective display area, and wherein
the parts of various metal lines which are located in the foldable region are the same in length.

12. The flexibly foldable display panel according to claim 11, wherein the GOA circuit unit is connected to the effective display area through one or more gate lines.

13. The flexibly foldable display panel according to claim 12, wherein the lengths of the lines from the GOA circuit unit to the effective display area are all the same.

14. The flexibly foldable display panel according to claim 11, wherein a part of the metal line located in the foldable region is in a shape of S, arc, or folding when it is projected on the substrate.

15. The flexibly foldable display panel according to claim 11, wherein the inorganic layer comprises SiNx and/or SiOy, wherein x≥1 and y≥1, and wherein
the substrate is made of a polyimide material, and
the organic layer is a photoresist material or an organic insulating material.

16. A flexibly foldable display panel, comprising at least two non-foldable regions and a foldable region between the two adjacent non-foldable regions, two sides of the foldable region being respectively connected with the two adjacent non-foldable regions and formed a one-piece structure therewith, wherein
each of the non-foldable regions is provided with a GOA circuit unit, the at least two non-foldable regions contain all GOA circuit units in the display panel, and the GOA circuit units in the two non-foldable regions are electrically connected to each other,
the foldable region is provided with metal lines and an organic layer upwardly on a substrate, and the non-foldable region is provided with an inorganic layer, metal lines, the GOA circuit unit and an organic layer upwardly on a substrate,
a part of the metal line located in the foldable region is in a shape of S, arc, or folding when it is projected on the substrate, and
the parts of various metal lines which are located in the foldable region are the same in length.

17. The flexibly foldable display panel according to claim 16, wherein the display panel includes an effective display area and a non-effective display area around the effective display area, the GOA circuit unit is located in the non-effective display area, and the GOA circuit unit is electrically connected to the effective display area.

18. The flexibly foldable display panel according to claim 17, wherein the GOA circuit unit is connected to the effective display area through one or more gate lines.

19. The flexibly foldable display panel according to claim 18, wherein the lengths of the lines from the GOA circuit unit to the effective display area are all the same.

20. The flexibly foldable display panel according to claim 16, wherein the inorganic layer comprises SiNx and/or SiOy, wherein x≥1 and y≥1, and wherein
the substrate is made of a polyimide material, and
the organic layer is a photoresist material or an organic insulating material.
